(19) United States
(12) Patent Application Publication
(10) Pub. No.: US 2024/0178157 A1
(43) Pub. Date: May 30, 2024

(54) SHAPE MEMORY POLYMER (SMP) GLASS CORE PACKAGE FOR MODULATING WARPAGE

(71) Applicant: Intel Corporation, Santa Clara, CA (US)

(72) Inventors: Vinith BEJUGAM, Chandler, AZ (US); Whitney BRYKS, Tempe, AZ (US); Brandon C. MARIN, Gilbert, AZ (US); Vishal Bhimrao ZADE, Chandler, AZ (US); Deniz TURAN, Chandler, AZ (US); Srinivas V. PIETAMBARAM, Chandler, AZ (US)

(21) Appl. No.: 18/071,257

(22) Filed: Nov. 29, 2022

(51) Int. Cl. H01L 23/00; H01L 23/498

(52) U.S. Cl. CPC H01L 23/562; H01L 23/49822

(57) ABSTRACT

Embodiments disclosed herein include package substrates. In a particular embodiment, the package substrate comprises a core. The core may be a glass core. In an embodiment, buildup layers are provided over the core, and a shape memory polymer (SMP) is provided over the core.

### TECHNICAL FIELD

Embodiments of the present disclosure relate to electronic packages, and more particularly to package substrates with glass cores that include a shape memory polymer (SMP) that is used to mitigate package substrate warpage.

### BACKGROUND

Advanced packaging architectures are moving towards the inclusion of glass core substrates as opposed to organic core substrates. However, thermal and mechanical stresses caused by various processes in the assembly flow may lead to significant warpage of the package substrate. For example, warpages of 5 mm or more may be present in some packaging architectures that use glass cores. Traditionally, vacuum mechanisms (e.g., vacuum chucking) have been used to reduce the warpage. Applying mechanical forces to the package substrate for flattening does not work for significantly warped packages. Particularly, the mechanical stresses can lead to cracks or other defects in the glass core. Additionally, there are not many other options for reducing warpage at the panel level of assembly.

### BRIEF DESCRIPTION OF THE DRAWINGS

FIG. 1A is a cross-sectional illustration of a shape memory polymer (SMP) that is in an unactuated state, in accordance with an embodiment.

FIG. 1B is a cross-sectional illustration of the SMP when one end of the SMP is actuated, in accordance with an embodiment.

FIG. 1C is a cross-sectional illustration of the SMP when both ends of the SMP are actuated, in accordance with an embodiment.

FIG. 2A is a cross-sectional illustration of a package substrate with a glass core and an SMP over a top buildup layer, in accordance with an embodiment.

FIG. 2B is a cross-sectional illustration of a package substrate with a glass core and an SMP over a bottom buildup layer, in accordance with an embodiment.

FIG. 2C is a cross-sectional illustration of a package substrate with a glass core and an SMP directly on the glass core, in accordance with an embodiment.

FIG. 2D is a cross-sectional illustration of a package substrate with a glass core and an SMP embedded in the top buildup layers, in accordance with an embodiment.

FIG. 3A is a cross-sectional illustration of a package substrate with SMP regions that are being actuated by an electromagnet tool, in accordance with an embodiment.

FIG. 3B is a plan view illustration of a package substrate with an active region and a keep out zone (KOZ), where the SMP regions are in the KOZ, in accordance with an embodiment.

FIG. 4 is a cross-sectional illustration of a computing system that includes a package substrate with a glass core and one or more SMP regions, in accordance with an embodiment.

FIG. 5 is a schematic of a computing device built in accordance with an embodiment.

### EMBODIMENTS OF THE PRESENT DISCLOSURE

Described herein are package substrates with glass cores that include a shape memory polymer (SMP) that is used to mitigate package substrate warpage, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, package substrates with glass cores are susceptible to warpage. Warpage can lead to assembly issues, such as limited depth of focus of lithography and/or laser processes. Warpage can also negatively impact component assembly operations. Existing panel level solutions for controlling warpage, such as vacuum chucking, may lead to excess stress and strain in the package substrate. This may result in damage (e.g., cracking, etc.) to the core. A damaged core poses reliability concerns and needs to be avoided.

Accordingly, embodiments disclosed herein include shape memory polymers (SMPs) that are used to mitigate or eliminate warpage of the package substrate. SMPs are particularly beneficial because they can be selectively articulated in order to match the warpage of the package substrate. For example, the magnetic orientation of the SMP may be such that a first end and a second end can be independently controlled in order to locally tune the warpage mitigation efforts.

SMP materials may have shape memory actuation through different external stimuli. In one embodiment, thermal energy (heat) may be applied to the SMP in order to initiate the actuation. In other embodiments, a magnetic induction process may be used in order to initiate the actuation. In the case of thermal actuation, the SMP may include a poly (ether ether ketone) (PEEK) material. The PEEK material may be sulfonated in some embodiments. For example, the sulfonation levels may be up to approximately 20 mol percent. As used herein, “approximately” may refer to a range of values that are within ten percent of the stated value. For example, approximately 20 may refer to a range between 18 and 22. PEEK materials may be actuated by the application of heat and/or cooling. In the case of magnetic induction, the SMP may include magnetic particles that are provided in an acrylate based amorphous polymer. For example, the magnetic particles may comprise iron and oxygen (e.g., FeO₄), neodymium, iron, and boron (e.g., NdFeB), and/or nickel, iron and boron (e.g., NiFeB). A magnetic field may be applied to the SMP in order to induce actuation.

In an embodiment, the SMPs may be provided in one or more different locations of the package substrate. In some embodiments, the SMP may be provided over topmost buildup layers, or bottommost buildup layers. In other embodiments, the SMP may be provided directly over the core (e.g., a glass core). In yet another embodiment, the SMP may be embedded within the top or bottom buildup layers. Furthermore, embodiments may include a plurality of SMP regions that are provided in a keep out zone (KOZ) around an outer perimeter of the package substrate. In some embodiments, the SMP may be used as a carrier for fabricating the package substrate.

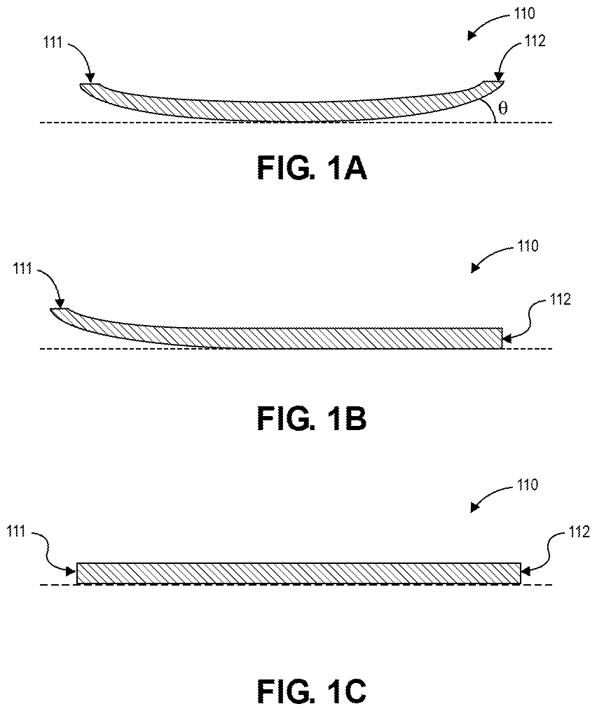

Referring now to FIGS. 1A-1C, cross-sectional illustrations of SMP 110 materials are shown, in accordance with an embodiment. As used herein, a SMP 110 material is a polymer material that is actuatable between at least two different shapes. In an unactuated state, the SMP may be at the base shape. In FIG. 1A, an SMP 110 is provided in an unactuated base shape. That is, the shape of the SMP 110 in FIG. 1A is the shape that is stored in the “memory” of the SMP 110. After an initial actuation, the SMP 110 may be reset to this base shape (e.g., by application of heat or magnetic field). As shown, the SMP 110 has a first end 111 and a second end 112. The first end 111 and the second end 112 may be curved up an angle θ from a planar surface (indicated with a dashed line). In some instances (as shown in FIG. 1A), the end surfaces (i.e., sidewalls) of the SMP 110 may be curved so that they face upwards. Though, embodiments are not limited to such architectures. In an embodiment, the first end 111 and the second end 112 are bent in the same direction (upwards). In other embodiments, the curvature of the first end 111 and the second end 112 may be different. For example, the first end 111 may be substantially flat, and the second end 112 may be curved upward. Alternatively, the first end 111 may be curved downward and the second end 112 may be curved upward. In other embodiments, the base shape of the SMP 110 may be substantially planar so that neither the first end 111 or the second end 112 curves upward or downward.

In an embodiment SMP materials may have shape memory actuation through different external stimuli. In one embodiment, thermal energy (heat) may be applied to the SMP 110 in order to initiate the actuation. In other embodiments, a magnetic induction process may be used in order to initiate the actuation. In the case of thermal actuation, the SMP 110 may include a PEEK material. The PEEK material may be sulfonated in some embodiments. For example, the sulfonation levels may be up to approximately 20 mol percent. In the case of magnetic induction, the SMP 110 may include magnetic particles that are provided in an acrylate based amorphous polymer. For example, the magnetic particles may comprise iron and oxygen (e.g., FeO₄), neodymium, iron, and boron (e.g., NdFeB), and/or nickel, iron and boron (e.g., NiFeB).

Referring now to FIG. 1B, a cross-sectional illustration of the SMP 110 after a first actuation is shown, in accordance with an embodiment. As shown, the first actuation may result in the second end 112 of the SMP 110 being actuated so that the second end 112 is flat against the planar surface. The actuation may be induced through the use of thermal energy and/or a magnetic induction. Furthermore, it is to be appreciated that the actuation may be selective in that only a portion of the SMP 110 is actuated. That is, the first end 111 of the SMP 110 may remain in the curved position. The selective actuation of the SMP 110 can be used in order to fine tune the warpage mitigation of the package substrate (not shown in FIGS. 1A-1C).

In an embodiment, the actuation may be implemented by the application of thermal energy and/or magnetic induction that is temporary. That is, the thermal energy and/or magnetic induction can be applied for a duration of time and then is released. After release of the external stimuli, the actuated state of the SMP 110 persists. This allows for warpage mitigation that does not require continuous power. As such, power consumption is decreased in the fabrication of the package substrate. If the actuation needs to be reset to the default shape (e.g., FIG. 1A), then the SMP 110 may be heated again which allows for a shape reset.

Referring now to FIG. 1C, a cross-sectional illustration of the SMP 110 after a second actuation is shown, in accordance with an embodiment. As shown, the first end 111 is now actuated so that the first end 111 lies flat against the planar surface. Similar to the actuation in FIG. 1B, the second actuation may be implemented with the application of external stimuli, such as heat or magnetic induction. The type of external stimuli may be the same stimuli used in the first actuation. While two different actuation operations are shown in FIG. 1B and FIG. 1C, it is to be appreciated that the actuation of both the first end 111 and the second end 112 may be implemented with a single external stimuli.

The actuation of the first end 111 and the second end 112 may be used in order to mitigate warpage of a package substrate. For example, the warpage of the package substrate may be dished shaped. In such an embodiment, the inclusion of the SMP 110 over the dished surface may be used to mitigate the warpage. That is, the curved up ends of the SMP 110 may be actuated down in order to flatten out the dished shaped warpage. Of course the SMP 110 may be designed to accommodate other types of warpages as well, depending on how the SMP 110 actuates from the base shape.

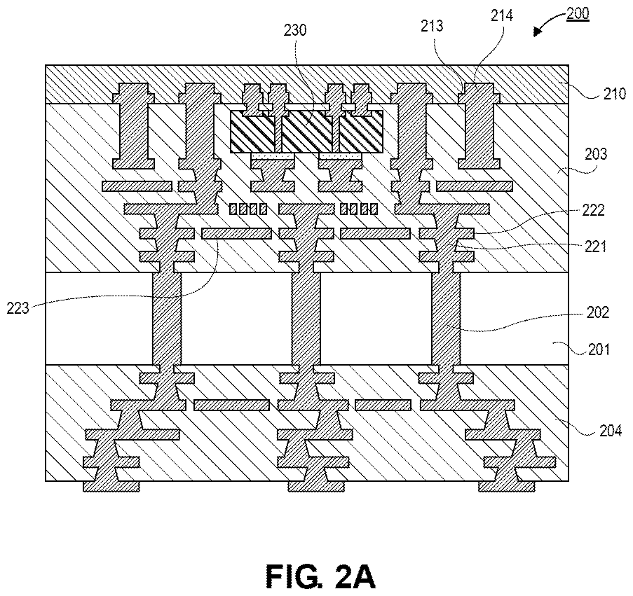

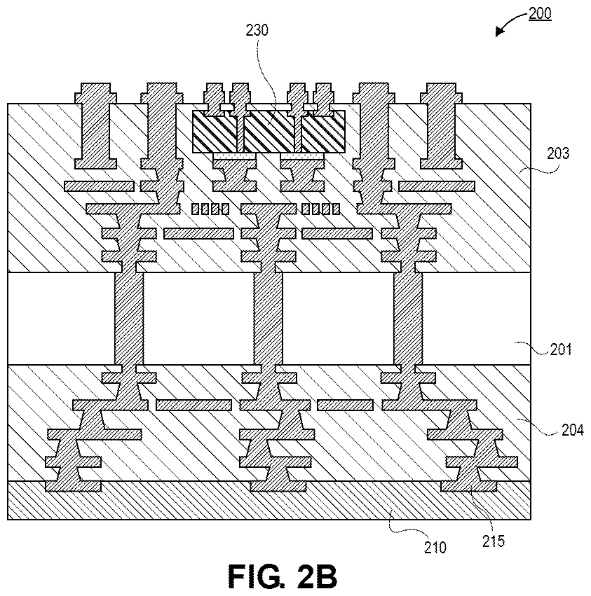

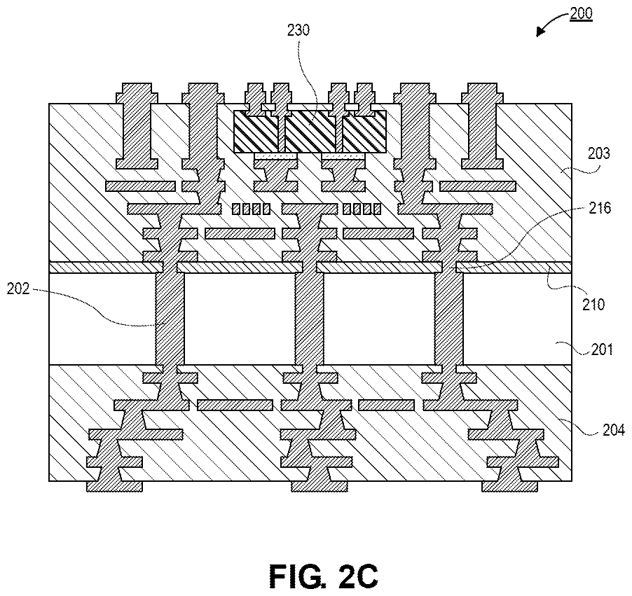

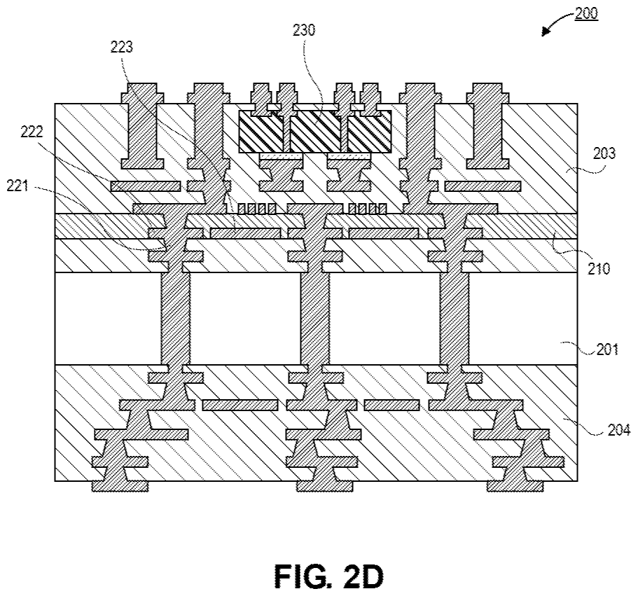

Referring now to FIG. 2A, a cross-sectional illustration of a package substrate 200 is shown, in accordance with an embodiment. In an embodiment, the package substrate 200 may include some degree of warpage. The warpage may be mitigated through the use of an SMP 210. In the illustrated embodiment, the SMP 210 is shown as a substantially continuous sheet across the surface of the package substrate 200. Though, as will be described in greater detail below, a plurality of SMP regions may also be used in some embodiments.

In an embodiment, the package substrate 200 may comprise a core 201. The core 201 may be a glass core 201 in some embodiments. That is, the core 201 may comprises substantially all glass with through glass vias (TGVs) 202 that pass through a thickness of the core 201. In an embodiment, the glass may comprise a borosilicate glass, a fused silica glass, aluminosilicate glass, or the like. In some embodiments, the core 201 may also be an organic core. In a particular embodiment, the glass of the core 201 may be a glass material that is compatible with laser assisted patterning or laser assisted etching processes. That is, a laser may expose regions of the core 201 that are desired to be etched. The laser exposure alters the phase and/or microstructure of the glass in order to render the exposed regions more susceptible to a wet etching chemistry. The etching process forms via openings, and the TGVs 202 can then be plated in the via openings. The TGVs 202 may be formed by depositing a seed layer (e.g., through sputtering, electroless deposition, or atomic layer deposition) and then using electrolytic plating to plate up the TGVs 202.

In an embodiment, the glass core 201 may have a thickness that is suitable for forming the package substrate 200 with desired mechanical characteristics. For example, the glass core 201 may have a thickness that is up to approximately 1,000 μm thick. Though, even thicker cores 201 may be used in some embodiments. In an embodiment, the glass core 201 may result in some degree of warpage in the package substrate 200. The warpage may be attributable to different coefficients of thermal expansion (CTE) between the core 201 and the buildup layers 203/204 above/below the core 201. In some embodiments, warpage values may be approximately 5 mm or more. Such large warpages may result in assembly difficulty and/or difficulty patterning features due to a shallow depth of focus of patterning technologies (e.g., lithography, laser exposure, etc.).

In an embodiment, the package substrate 200 comprises buildup layers 203 above the core 201 and buildup layers 204 below the core 201. The buildup layers 203/204 may comprise a dielectric material, such as a buildup film. The buildup layers 203/204 may be formed with a lamination process or the like. Additionally, conductive features may be embedded in the buildup layers 203/204. For examples, pads 222, vias 221, and traces 223 may be formed in the buildup layers 203/204. The conductive features may comprise copper or other conductive materials. In some instances, seed layers (not shown) may also be provided between the conductive features and the buildup layers 203/204.

In some embodiments, one or more bridges 230 may be embedded in the top buildup layers 203. The bridge 230 may include high density routing in order to communicatively couple together a pair of dies (not shown) that are attached over the package substrate 201. In an embodiment, the bridge 230 may also comprise through silicon vias (TSVs) that pass through a thickness of the bridge 230 in order to enable backside power delivery or the like.

In a particular embodiment, a SMP 210 may be provided over a topmost surface of the buildup layers 203. The SMP 210 may be similar to any of the SMP materials described in greater detail above. For example, the SMP 210 may comprise a material that is actuated by the application of thermal energy and/or magnetic induction. For example, a PEEK based material or a material with magnetic particles in an acrylate based amorphous polymer may be used in some embodiments. In the illustrated embodiment, the SMP 210 is in an actuated state in order to mitigate warpage of the package substrate 200. For example, the warpage in the package substrate 200 is substantially eliminated. In an embodiment, both ends of the SMP 210 may be actuated so that the SMP 210 is substantially flat. That is, the base (unactuated) shape of the SMP 210 may be dish shaped in some embodiments.

In a particular embodiment, a thickness of the SMP 210 may be approximately 10 μm or greater. In the particular embodiment shown in FIG. 2A, the thickness of the SMP 210 is greater than the combined thickness of the top pads 213 and interconnects 214. In such an embodiment, openings may be subsequently formed through portions of the SMP 210 in order to connect overlying dies (not shown). However, in other embodiments, the thickness of the SMP 210 may be thinner than the combined thickness of the top pads 213 and the interconnects 214.

Referring now to FIG. 2B, a cross-sectional illustration of a package substrate 200 is shown, in accordance with an additional embodiment. In an embodiment, the package substrate 200 may comprise a core 201. The core 201 may be a glass core. For example, the core 201 in FIG. 2B may be substantially similar to the core 201 described with respect to FIG. 2A. In an embodiment, buildup layers 203 may be provided above the core 201, and buildup layers 204 may be provided below the core 201. In an embodiment, one or more bridge dies 230 may also be embedded in the buildup layer 203. The bridge die 230 in FIG. 2B may be substantially similar to the bridge die 230 described with respect to FIG. 2A. In an embodiment, conductive features (e.g., pads, vias, traces, etc.) may also be embedded in the buildup layers 203/204.

In an embodiment, the package substrate 200 may further comprise an SMP 210. As shown, the SMP 210 may be provided over a bottommost buildup layer 204. The SMP 210 may be provided over pads 215 on the bottom side of the package substrate 200. Openings (not shown) through the SMP 210 may be provided in order to provide electrical access to the pads 215. In an embodiment, the SMP 210 may have a thickness that is approximately 10 μm or more. The thickness of the SMP 210 may be greater than a thickness of the pads 215 in some embodiments. Though, in other embodiments, the SMP 210 may have the same thickness or a smaller thickness than the pads 215. The SMP 210 may be in direct contact with the buildup layers 204.

In an embodiment, the SMP 210 may comprise any suitable SMP material, such as those described in greater detail above. For example, the SMP 210 may be a material that can be actuated using one or both of a thermal stimulus or magnetic induction. In the illustrated embodiment, both ends of the SMP 210 are actuated so that the SMP 210 has a substantially flat cross-sectional profile. Though, in other embodiments, the SMP 210 may have one side actuated and the other side may remain unactuated.

Referring now to FIG. 2C, a cross-sectional illustration of a package substrate 200 is shown, in accordance with an additional embodiment. In an embodiment, the package substrate 200 may comprise a core 201. The core 201 may be a glass core. For example, the core 201 in FIG. 2C may be substantially similar to the core 201 described with respect to FIG. 2A. In an embodiment, buildup layers 203 may be provided above the core 201, and buildup layers 204 may be provided below the core 201. In an embodiment, one or more bridge dies 230 may also be embedded in the buildup layer 203. The bridge die 230 in FIG. 2C may be substantially similar to the bridge die 230 described with respect to FIG. 2A. In an embodiment, conductive features (e.g., pads, vias, traces, etc.) may also be embedded in the buildup layers 203/204.

In an embodiment, the package substrate 200 may further comprise an SMP 210. As shown, the SMP 210 may be provided directly over the top surface of the core 201. That is, the SMP 210 may directly contact the core 201 in some embodiments. In an embodiment, the SMP 210 may have a thickness that is approximately 10 μm or more. The thickness of the SMP 210 may be substantially equal to the thickness of an individual buildup layer 203 in the stack of buildup layers 203. As shown, vias 216 may be provided through the SMP 210 in order to access the TGVs 202 in the core 201. While a single SMP 210 is shown over the top surface of the core 201, it is to be appreciated that a second SMP 210 may be provided over the bottom surface of the core 201. Alternatively, an SMP 210 may be provided only over the bottom surface of the core 201.

In an embodiment, the SMP 210 may comprise any suitable SMP material, such as those described in greater detail above. For example, the SMP 210 may be a material that can be actuated using one or both of a thermal stimulus or magnetic induction. In the illustrated embodiment, both ends of the SMP 210 are actuated so that the SMP 210 has a substantially flat cross-sectional profile. Though, in other embodiments, the SMP 210 may have one side actuated and the other side may remain unactuated.

Referring now to FIG. 2D, a cross-sectional illustration of a package substrate 200 is shown, in accordance with an additional embodiment. In an embodiment, the package substrate 200 may comprise a core 201. The core 201 may be a glass core. For example, the core 201 in FIG. 2D may be substantially similar to the core 201 described with respect to FIG. 2A. In an embodiment, buildup layers 203 may be provided above the core 201, and buildup layers 204 may be provided below the core 201. In an embodiment, one or more bridge dies 230 may also be embedded in the buildup layer 203. The bridge die 230 in FIG. 2D may be substantially similar to the bridge die 230 described with respect to FIG. 2A. In an embodiment, conductive features (e.g., pads, vias, traces, etc.) may also be embedded in the buildup layers 203/204.

In an embodiment, the package substrate 200 may further comprise an SMP 210. As shown, the SMP 210 may be embedded in the buildup layers 203. That is, the top surface and the bottom surface of the SMP 210 may both directly contact the buildup layers 203 in some embodiments. In an embodiment, the SMP 210 may have a thickness that is approximately 10 μm or more. The thickness of the SMP 210 may be substantially equal to the thickness of an individual buildup layer 203 in the stack of buildup layers 203. As shown, vias 221, traces 223, and pads 222 may be provide on and/or through the SMP 210. While a single SMP 210 is shown embedded in the buildup layer 203, it is to be appreciated that a plurality of SMPs 210 may be provided in the buildup layers 203. Alternatively, (or in addition) one or more SMPs 210 may be provided in the buildup layers 204 below the core 201.

In an embodiment, the SMP 210 may comprise any suitable SMP material, such as those described in greater detail above. For example, the SMP 210 may be a material that can be actuated using one or both of a thermal stimulus or magnetic induction. In the illustrated embodiment, both ends of the SMP 210 are actuated so that the SMP 210 has a substantially flat cross-sectional profile. Though, in other embodiments, the SMP 210 may have one side actuated and the other side may remain unactuated.

In the embodiments shown in FIGS. 2A-2D, separate examples of where the SMP 210 can be located are shown. However, it is to be appreciated that multiple SMPs 210 can be located in more than one location shown in FIGS. 2A-2D. For example, a first SMP 210 can be provided over the top buildup layers 203, and a second SMP 210 can be embedded in the top buildup layers 203. Though, it is to be appreciated that other combinations of the embodiments shown in FIGS. 2A-2D can be used as well.

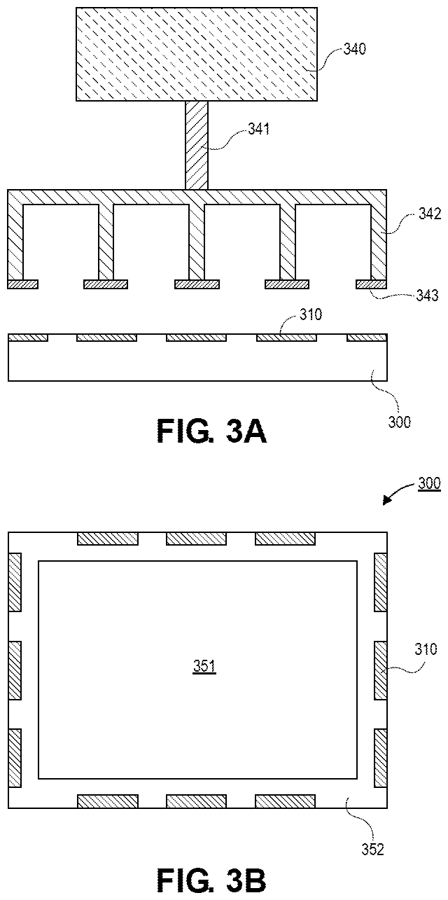

Referring now to FIGS. 3A and 3B, an alternative architecture is shown, in accordance with an embodiment. As shown in FIGS. 3A and 3B, a plurality of discrete SMP regions 310 are provided on a single package substrate 300. More particularly, the SMP regions 310 are located along a perimeter of the package substrate 300 in a keep out zone (KOZ).

Referring now to FIG. 3A, a cross-sectional illustration of a package substrate 300 is shown, in accordance with an embodiment. In an embodiment, the package substrate 300 comprises a plurality of SMP regions 310 that extend across an edge of the package substrate 300. In the illustrated embodiment, the SMP regions 310 are illustrated at a top of the package substrate 300. Though, it is to be appreciated that the SMP regions 310 may be provided at any position through the thickness of the package substrate 300 or at a bottom of the package substrate, similar to SMP 210 locations described in greater detail above.

In an embodiment, the SMP regions 310 may be actuated through the application of external stimuli. For example, in the embodiment shown in FIG. 3A, a series of electromagnets 343 are provided above the package substrate 300. Each electromagnet 343 may be provided along an arm 342 of a robotic tool 340. The arm 342 may be coupled to the main body of the robotic tool 340 by a connector 341. The connector 341 and arms 342 may provide an electrical path that can be used to activate individual ones of the electromagnets 343. Activation of the electromagnets 343 may provide a magnetic field that is strong enough to induce actuation of a given one of the SMP regions 310. The electromagnets 343 may be independently controlled in order to selectively activate individual ones of the SMP regions 310. As such, various different warpages can be mitigated using different combinations of the SMP regions 310.

Referring now to FIG. 3B, a plan view illustration of the package substrate 300 is shown, in accordance with an embodiment. In an embodiment, the package substrate 300 includes a device region 351 and a KOZ 352. The device region 351 may be at the center of the package substrate 300, and the KOZ 352 may be around a perimeter of the device region 351 at the edges of the package substrate 300. The KOZ 352 may be a region where active device circuitry is omitted. Instead, the KOZ 352 may house one or more SMP regions 310. For example, a set of three SMP regions 310 are provided along each edge of the package substrate 300. However, it is to be appreciated that any number of SMP regions 310 (e.g., one or more SMP regions) may be included in the KOZ 352. Moving the SMP regions 310 to the KOZ 352 allows for the warpage mitigation solution to be implemented without needing to significantly adjust the manufacturing and assembly of the device region 351 of the package substrate 300.

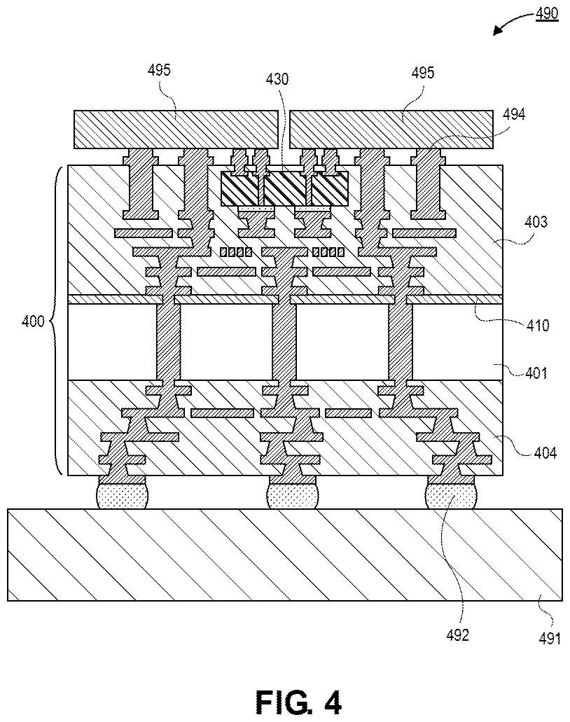

Referring now to FIG. 4, a cross-sectional illustration of a computing system 490 is shown, in accordance with an embodiment. In an embodiment, the computing system 490 comprises a board 491, such as a printed circuit board (PCB). The board 491 may be coupled to a package substrate 400 by interconnects 492. While shown as solder balls, it is to be appreciated that any interconnect architecture may be used for the interconnects 492.

In an embodiment, the package substrate 400 may comprise a core 401 and buildup layers 403 and 404. In an embodiment, the core 401 may comprise glass. In an embodiment, a SMP 410 may be provided on the package substrate 400. For example, FIG. 4 illustrates the SMP 410 being directly in contact with the core 401. However, it is to be appreciated that the SMP 410 may be provided in any location of the package substrate 400 described herein, or in multiple different locations. The SMP 410 may be actuated using thermal energy and/or magnetic induction.

In an embodiment, a bridge 430 may also be embedded in the package substrate 400. The bridge 430 may provide communicative coupling between a pair of dies 495 that are coupled to the package substrate by interconnects 494. The interconnects 494 may include any first level interconnect (FLI) architecture. The dies 495 may be any type of die, such as compute dies, memory dies, or the like.

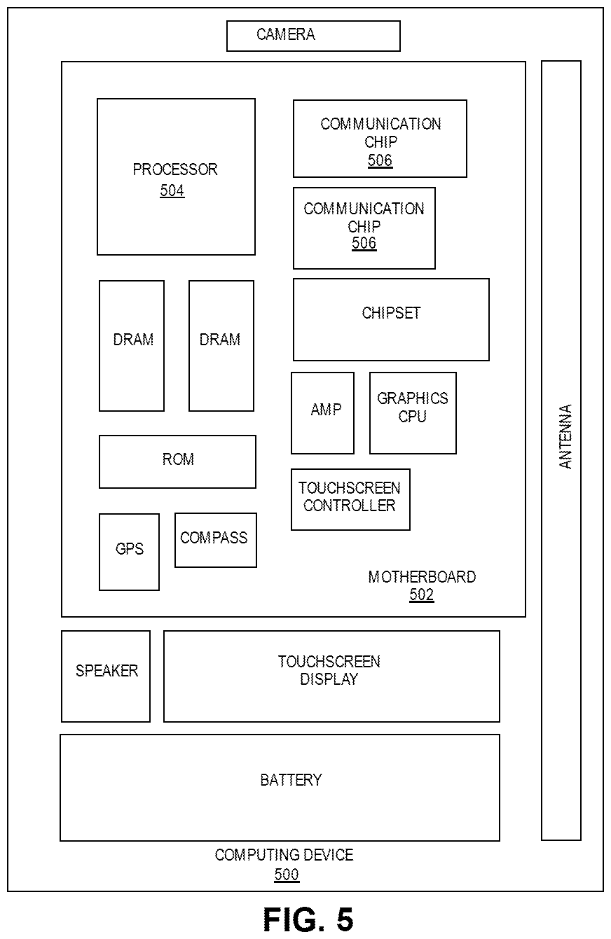

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be part of an electronic package that comprises a glass core with SMP regions for warpage mitigation, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be part of an electronic package that comprises a glass core with SMP regions for warpage mitigation, in accordance with embodiments described herein.

In an embodiment, the computing device 500 may be part of any apparatus. For example, the computing device may be part of a personal computer, a server, a mobile device, a tablet, an automobile, or the like. That is, the computing device 500 is not limited to being used for any particular type of system, and the computing device 500 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core; buildup layers over the core; and a shape memory polymer (SMP) over the core.

Example 2: the package substrate of Example 1, wherein the SMP is directly on a topmost buildup layer.

Example 3: the package substrate of Example 1 or Example 2, wherein the SMP is directly contacting the core.

Example 4: the package substrate of Examples 1-3, wherein the SMP is embedded in the buildup layers.

Example 5: the package substrate of Examples 1-4, wherein the SMP comprises poly (ether ether ketone) (PEEK).

Example 6: the package substrate of Example 5, wherein the PEEK is sulfonated.

Example 7: the package substrate of Examples 1-6, wherein the SMP comprises: magnetic particles.

Example 8: the package substrate of Example 7, wherein the magnetic particles comprise one or more of iron and oxygen, or neodymium, iron, and boron, or nickel, iron, and boron.

Example 9: the package substrate of Examples 1-8, wherein the SMP is provided in a keep out zone (KOZ) of the package substrate.

Example 10: the package substrate of Examples 1-9, wherein the SMP is actuated with a magnetic induction process.

Example 11: the package substrate of Examples 1-10, wherein the SMP is actuated with a heating process.

Example 12: the package substrate of Examples 1-11, wherein the SMP has a first end and a second end, and wherein the first end can be actuated without actuating the second end.

Example 13: the package substrate of Examples 1-12, wherein the package substrate is coupled to a processor of a computing system.

Example 14: a package substrate, comprising: a core; buildup layers over the core, wherein the package substrate comprises a keep out zone (KOZ) around a perimeter of the package substrate; and a shape memory polymer (SMP) positioned in the KOZ of the package substrate.

Example 15: the package substrate of Example 14, wherein the SMP comprises poly (ether ether ketone) (PEEK).

Example 16: the package substrate of Example 15, wherein the PEEK is sulfonated.

Example 17: the package substrate of Examples 14-16, wherein the SMP comprises: magnetic particles.

Example 18: the package substrate of Example 17, wherein the magnetic particles comprise one or more of iron and oxygen, or neodymium, iron, and boron, or nickel, iron, and boron.

Example 19: the package substrate of Examples 14-18, wherein a plurality of SMP regions are provided around a perimeter of the KOZ.

Example 20: the package substrate of Examples 14-19, wherein the SMP is configured to articulate with application of a magnetic field.

Example 21: the package substrate of Examples 14-20, wherein the SMP is configured to articulate with the addition of thermal energy.

Example 22: the package substrate of Examples 14-21, wherein the SMP has a first end and a second end, and wherein the first end and the second end can be independently articulated.

Example 23: a computing system, comprising: a board; a package substrate coupled to the board, wherein the package substrate comprises: a core; a buildup layer over the core; and a shape memory polymer (SMP) over the core; and a die coupled to the package substrate.

Example 24: the computing system of Example 23, wherein the SMP is in a keep out zone (KOZ) of the package substrate.

Example 25: the computing system of Example 23 or Example 24, wherein the computing system is part of a personal computer, a mobile device, a tablet, a server, or an automobile.

What is claimed is:

1. A package substrate, comprising:
a core;
buildup layers over the core; and
a shape memory polymer (SMP) over the core.

2. The package substrate of claim 1, wherein the SMP is directly on a topmost buildup layer.

3. The package substrate of claim 1, wherein the SMP is directly contacting the core.

4. The package substrate of claim 1, wherein the SMP is embedded in the buildup layers.

5. The package substrate of claim 1, wherein the SMP comprises poly (ether ether ketone) (PEEK).

6. The package substrate of claim 5, wherein the PEEK is sulfonated.

7. The package substrate of claim 1, wherein the SMP comprises:
magnetic particles.

8. The package substrate of claim 7, wherein the magnetic particles comprise one or more of iron and oxygen, or neodymium, iron, and boron, or nickel, iron, and boron.

9. The package substrate of claim 1, wherein the SMP is provided in a keep out zone (KOZ) of the package substrate.

10. The package substrate of claim 1, wherein the SMP is actuated with a magnetic induction process.

11. The package substrate of claim 1, wherein the SMP is actuated with a heating process.

12. The package substrate of claim 1, wherein the SMP has a first end and a second end, and wherein the first end can be actuated without actuating the second end.

13. The package substrate of claim 1, wherein the package substrate is coupled to a processor of a computing system.

14. A package substrate, comprising:
a core;
buildup layers over the core, wherein the package substrate comprises a keep out zone (KOZ) around a perimeter of the package substrate; and
a shape memory polymer (SMP) positioned in the KOZ of the package substrate.

15. The package substrate of claim 14, wherein the SMP comprises poly (ether ether ketone) (PEEK).

16. The package substrate of claim 15, wherein the PEEK is sulfonated.

17. The package substrate of claim 14, wherein the SMP comprises:
magnetic particles.

18. The package substrate of claim 17, wherein the magnetic particles comprise one or more of iron and oxygen, or neodymium, iron, and boron, or nickel, iron, and boron.

19. The package substrate of claim 14, wherein a plurality of SMP regions are provided around a perimeter of the KOZ.

20. The package substrate of claim 14, wherein the SMP is configured to articulate with application of a magnetic field.

21. The package substrate of claim 14, wherein the SMP is configured to articulate with the addition of thermal energy.

22. The package substrate of claim 14, wherein the SMP has a first end and a second end, and wherein the first end and the second end can be independently articulated.

23. A computing system, comprising:
a board;
a package substrate coupled to the board, wherein the package substrate comprises:
a core;
a buildup layer over the core; and
a shape memory polymer (SMP) over the core; and
a die coupled to the package substrate.

24. The computing system of claim 23, wherein the SMP is in a keep out zone (KOZ) of the package substrate.

25. The computing system of claim 23, wherein the computing system is part of a personal computer, a mobile device, a tablet, a server, or an automobile.
